(19) United States
(12) Patent Application Publication
(10) Pub. No.: US 2015/0137003 A1
(43) Pub. Date: May 21, 2015

(54) SPECIMEN PREPARATION METHOD

(71) Applicant: United Microelectronics Corp., Hsinchu (TW)

(72) Inventor: Kaeng-Nan Liew, Singapore (SG)

(73) Assignee: United Microelectronics Corp., Hsinchu (TW)

(21) Appl. No.: 14/086,820

(22) Filed: Nov. 21, 2013

(51) Int. Cl. H01J 37/305; G01N 1/32; H01J 37/20; G01N 1/28

(52) U.S. Cl. CPC H01J 37/305; G01N 1/2813; G01N 1/32; H01J 37/20; H01J 2237/2802; H01J 2237/2007; H01J 2237/208; H01J 2237/303
USPC 250/453.11

(57) ABSTRACT

A method of preparing ultra-thin TEM specimens is provided by flipping the sample upside down for FIB thinning Such preparation method is compatible with the ex-situ lift-out system and offers high quality TEM specimens without the curtaining effect.

### BACKGROUND OF THE INVENTION

1. Field of Invention

The present invention relates to a thinning method, and particularly to a specimen preparation method.

2. Description of Related Art

For physical characterization of the semiconductor devices, the transmission electron microscopy (TEM) specimen generally has a thickness of about 100 nm so as to be electron transparent at TEM accelerating voltage of 200 kV. However, at sub 30 nm technology node, the specimen needs to be as thin as 50 nm for structural characterization. Hence, low-energy focused ion beam (FIB) technology is used for preparing ultra thin TEM specimens.

Nevertheless, the ultra thin TEM specimens prepared by low-energy FIB technology frequently suffer severe curtaining effect. The curtaining effect is the formation of milling strips across the TEM sample made of different materials, propagating vertically from the heavy material to the other side of TEM sample. Such curtaining artifact may disturb the high resolution TEM analysis, especially for fine structures.

### SUMMARY OF THE INVENTION

The present invention provides a method of preparing ultra-thin TEM specimens, which flips the sample upside down for FIB thinning and utilizes the ex-situ lift-out technique. The obtained TEM specimens give high quality TEM images and the curtaining effect is precluded. Most importantly, the present invention does not require chamber-mounted microprobe for the sample preparation and therefore no additional cost is incurred.

The present invention provides a method of preparing a specimen. At first, a substrate is loaded into a focused ion beam (FIB) chamber. A TEM sample is cut out of the substrate by forming trenches in the substrate through FIB milling. Then, the sample is transferred outside of the FIB chamber to a grid. After loading the grid with the sample into the FIB chamber, a first metal strip is deposited over the sample in the FIB chamber. Then, the sample is transferred outside of the FIB chamber and the sample is inverted. After loading the inverted sample back to the FIB chamber, the inverted sample is thinned to achieve optimum thickness. Lastly, the specimen is unloaded out of the FIB chamber.

According to an embodiment of the present invention, in the step of transferring the sample outside of the FIB chamber to a grid, an orientation of the sample is adjusted by a probe needle so that the lamella carried on the grid is overturned when the grid is positioned upright.

According to an embodiment of the present invention, the grid and the lamella that placed on the grid are laid flat in the FIB chamber in the step of loading the sample lamella with the grid into the FIB chamber.

According to an embodiment of the present invention, after the step of transferring the grid with the TEM lamella outside of the FIB chamber and inverting the lamella, the grid is clamped by using fixtures.

According to an embodiment of the present invention, in the step of thinning the inverted sample in the FIB chamber, after the grid is clamped upright, the grid with the inverted lamella is loaded back into the FIB chamber for thinning until a predetermined thickness is achieved.

According to an embodiment of the present invention, the predetermined thickness of the specimens less than 100 nm.

According to an embodiment of the present invention, the grid is a U-shape copper grid having a silicon film thereon and the sample is placed on the silicon film.

According to an embodiment of the present invention, a second metal strip is plated on the lamella for lamella bonding to the silicon based film.

According to an embodiment of the present invention, the first metal strip or second metal strip is a platinum strip.

In order to make the aforementioned and other objects, features and advantages of the present invention comprehensible, a preferred embodiment accompanied with figures is described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a flowchart showing the steps of the preparation method for the TEM specimen according to one embodiment of the present invention.

FIGS. 2-9 show the schematic plane views of the process steps of the preparation method of the TEM specimen.

FIGS. 10A and 10B show two cross-sectional TEM micrographs of the TEM specimens.

### DESCRIPTION OF EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

In general, three types of focused ion beam (FIB) techniques may be used to prepare TEM specimens, including the H-bar technique, the ex-situ lift-out (EXLO) technique and the in-situ lift-out (INLO) technique. For the H-bar technique, a small sample is cut out from the bulk substrate using a diamond saw, and the cut-out sample lamella is mounted on a TEM grid after being polished by a polisher. Then, the focused ion beam (FIB) thinning process is performed until the sample is thin enough to create an electron transparent area. For the ex-situ lift-out technology, the cut-out lamella is transferred out of the chamber as the lift-out step (transferring the cut-out sample lamella) and the lifted-out sample lamella is placed on a thin carbon support film on TEM grid. As the lift-out step is performed outside of the FIB chamber, the instrumentation set-up is simple and cost efficient and a higher sample preparation throughput is offered. However, sample re-processing or inverted thinning is not allowed for the conventional ex-situ lift-out technology. On the other hand, the in-situ lift-out technique requires the manipulator tool (such as a microprobe) installed in the FIB chamber to perform the lift-out step inside the chamber (i.e. in-situ) and such system modification or upgrade is considerably much more expensive than the ex-situ lift-out technique.

In order to eliminate curtaining effect, the present invention proposes a thinning method that sample is flipped upside down (inverted) for FIB milling. The sample is transferred onto a U-shape copper grid with silicon support film outside of FIB chamber with a specific orientation, back into FIB chamber for platinum (Pt) plating and then the grid is clamped upright outside of FIB chamber to make the sample inverted. The thinning method of the present invention is compatible with the existing FIB ex-situ lift-out system and is used together with a U-shape copper ring for precise TEM sample preparation of semiconductor devices.

For the thinning method of the present invention, the cut-out sample lamella is transferred outside the FIB chamber by a probe needle (i.e. a glass needle) and the microprobe can rotate certain degrees (e.g. 180 degrees) for placing the sample onto a copper ring at a specific orientation so that the sample is positioned upside down when the copper ring is subsequently clamped upright on FIB holder. Hence, the system for performing the thinning method of the present invention does not require chamber-mounted microprobe for sample preparation, which is practical and cost-economic.

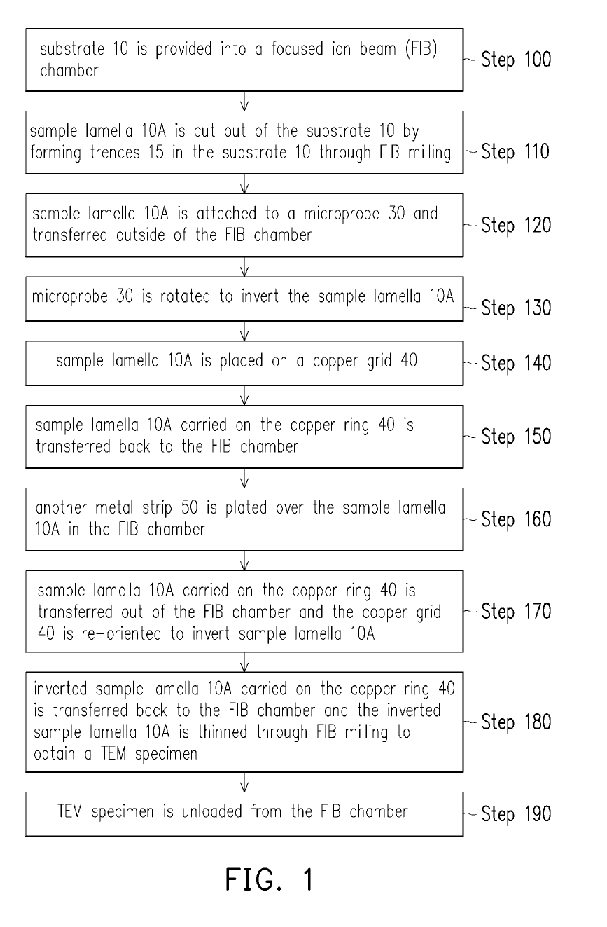

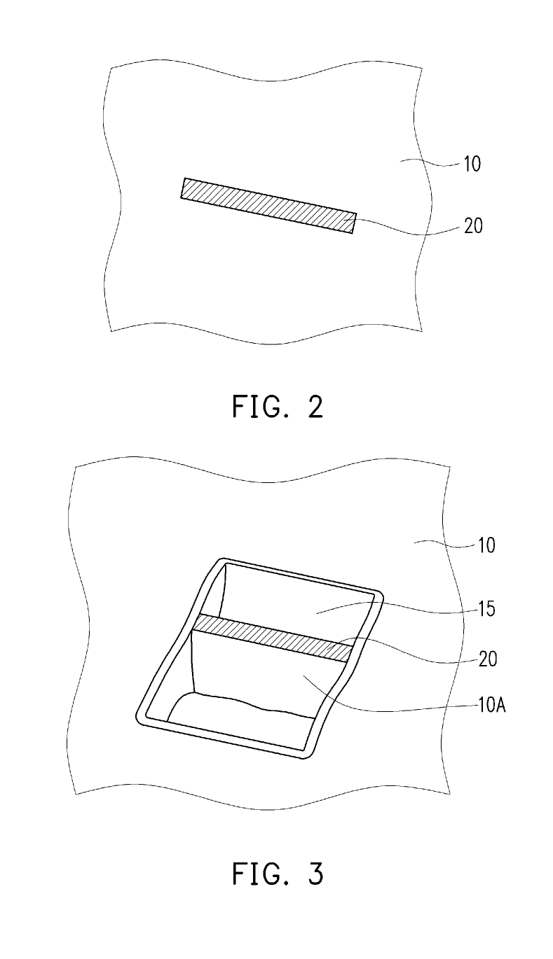

FIG. 1 is a flowchart showing the steps of the preparation method for the TEM specimen according to one embodiment of the present invention. FIGS. 2-9 show the schematic plane views of the process steps of the preparation method of the TEM specimen. The detailed explanation of each step is illustrated below.

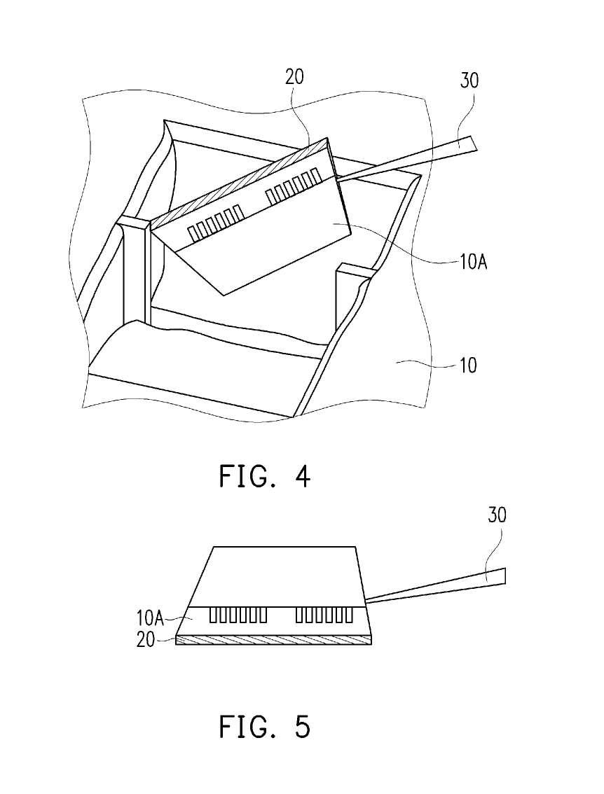

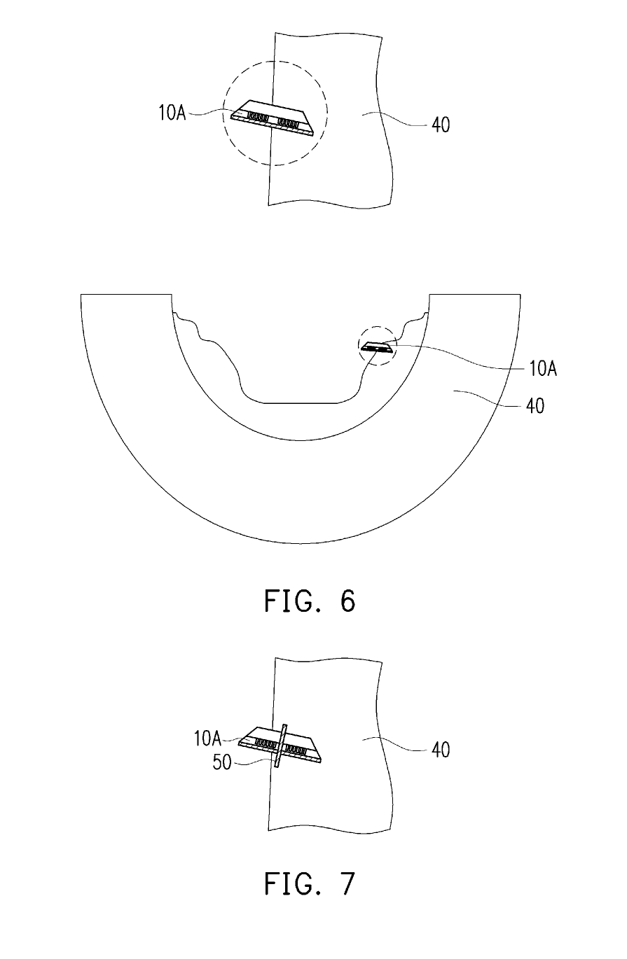

As shown in FIGS. 1 and 2, in Step 100, a bulk sample 10 is provided into a focused ion beam (FIB) chamber (not shown). At a specific position (the area of interest), a metal strip 20 is formed on the surface of bulk sample 100 within the FIB chamber. The metal strip 20 may be a platinum strip formed by ion beam assisted chemical vapour deposition, for example. As shown in FIGS. 1 and 3, in Step 110, a sample 10A is cut out of the bulk sample 10 by forming trenches 15 around the area of interest through FIB milling. For example, the FIB milling is performed at 30 keV. As shown in FIGS. 1 and 4, in Step 120, the sample 10A is attached to a probe needle 30 through electrostatic forces and transferred outside of the FIB chamber. The probe may be a glass probe, for example. Outside of the chamber, as shown in FIGS. 1 and 5, in Step 130, the probe 30 is rotated (for example, 180 degrees), to overturn the sample 10A (i.e. turn the sample 10A upside down), so that the platinum strip 20 on the sample lamella 10A turns down to face the bottom (in FIG. 5). Later, as shown in FIGS. 1 and 6, in Step 140, the sample 10A is placed onto a copper grid 40. For example, the copper grid 40 is a silicon base supported U-shape copper grid. The grid may be hold by an ion miller specimen holder and then placed on the FIB carrier. In Step 150, the sample 10A carried on the copper ring 40 is transferred back to the FIB chamber. Herein, the copper ring 40 and the sample lamella 10A lie flat in the FIB chamber. As shown in FIGS. 1 and 7, in Step 160, another metal strip 50 is deposited over the sample lamella 10A in the FIB chamber. The metal strip 50 may be a platinum strip formed by chemical vapour deposition, for example.

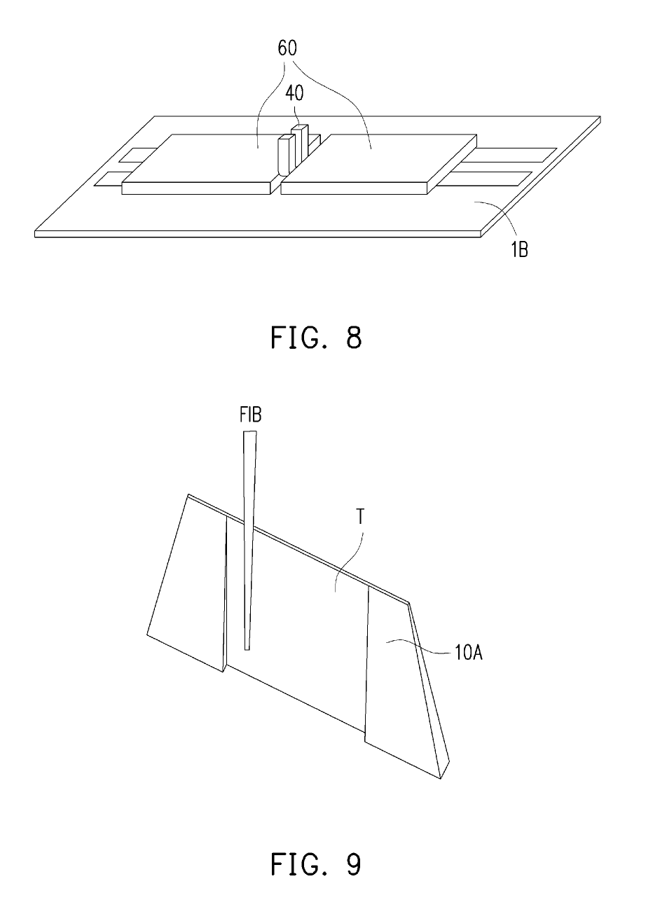

As shown in FIGS. 1 and 8, in Step 170, the copper ring 40 and the sample 10A carried on the copper ring 40 are transferred out of the FIB chamber and the copper grid 40 is re-oriented (the configuration shown as in FIG. 8) so that the sample 10A carried on the copper grid 40 is inverted (i.e. the platinum strip 20 on the sample lamella 10A faces the chamber bottom). For example, the copper grid 40 is positioned vertically relative to the chamber bottom surface 1B. The copper grid 40 is clamped by two fixtures 60. For example, the fixtures 60 may be square wafer slices. Later, as shown in FIGS. 1 and 9, in Step 180, the inverted lamella 10A carried on the copper ring 40 is transferred back to the FIB chamber. The inverted sample 10A is tilted so that the ion beam is transverse to the vertical axis of the sample 10A. The inverted sample 10A is thinned through FIB milling until an electron transparent portion T of a desirable thickness is formed and a desired TEM specimen is produced. Preferably, the obtained specimen has a thickness less than 100 nm. Preferably, the obtained specimen lamella has a thickness ≦50 nm or even 30 nm, for example.

In Step 190, the TEM specimen is unloaded from the FIB chamber.

During the thinning process in Step 180, the lamella 10A may be transferred into a transmission electron microscope for observation to judge whether the thickness of the sample is thin enough. If the sample thickness is uniform and thin enough for the transmission electron microscopy, the lamella is ready for TEM analysis. Otherwise, the lamella 10A may be transferred back into the FIB chamber for further thinning

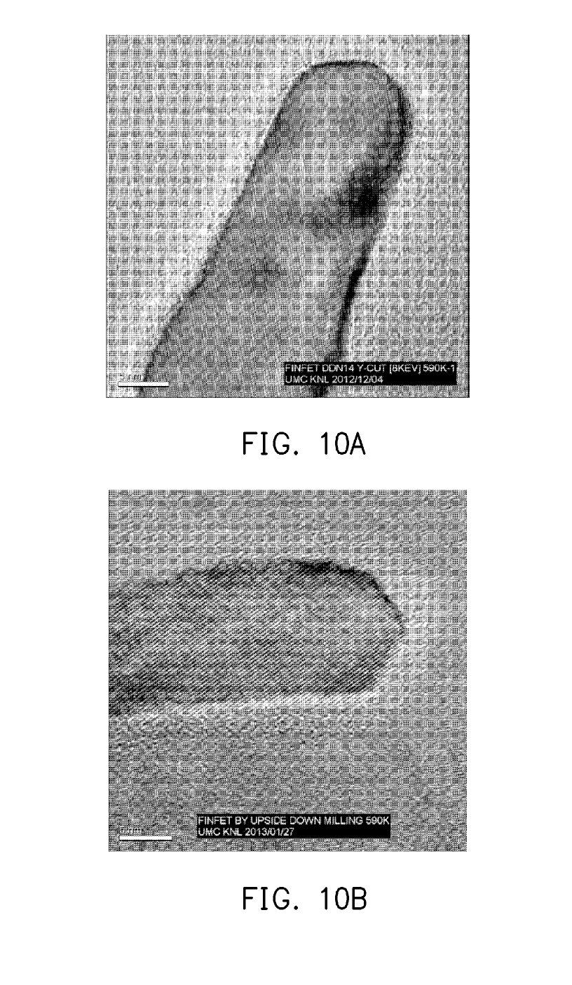

FIGS. 10A and 10B show two cross-sectional TEM micrographs of the TEM specimens having FinFET structures. Compared with the sample prepared by the conventional ex-situ lift-out technology of FIG. 10A, the TEM lamella of FIG. 10B is prepared using the preparation method according to the above example shows a clearer image of silicon lattice, owing to the sample lamella thickness. The sample of FIG. 10A is relatively thicker and shows poor phase contrast of the lattice image, while the sample lamella of FIG. 10B is relatively thinner and shows better phase contrast of the lattice image.

The present invention provides a method of producing ultra-thin TEM specimens, which is compatible with the existing ex-situ lift-out system. Also, the thinning method of the present invention can be performed in the existing ex-situ lift-out system without installing additional chamber-mounted microprobe for sample preparation, which effectively lowers the sample preparation costs. The preparation method of the present invention makes sample re-processing (i.e. sample re-thinning) possible, which is unfeasible for conventional ex-situ lift-out technology. Hence, the TEM specimen prepared according to the thinning method of this invention can obtain the optimum thickness for even high resolution TEM imaging.

Moreover, multiple specimens can be placed onto one copper grid for TEM analysis and the sample can be transferred back to the FIB chamber after TEM analysis if further thinning is needed.

As the procedure for transferring the lamella to the grid is performed faster outside the FIB chamber, the time required for preparation of the specimen can thus be reduced.

In summary, the preparation method of this invention provides high throughput preparation for TEM specimens and the TEM specimens produced by the thinning method of this invention can give high quality TEM images. Also, the prior problems such as the curtaining effect may be avoided as the sample lamella is inverted for FIB milling.

The present invention has been disclosed above in the preferred embodiments, but is not limited to those. It is known to persons skilled in the art that some modifications and innovations may be made without departing from the spirit and scope of the present invention. Therefore, the scope of the present invention should be defined by the following claims.

What is claimed is:

1. A method of preparing a specimen, comprising:
providing a bulk sample into a focused ion beam (FIB) chamber;
cutting a lamella out of the substrate as a sample by forming trenches in the bulk sample through FIB milling;
transferring the sample outside of the FIB chamber to a grid;
loading the sample with the grid into the FIB chamber;
plating a first metal strip over the sample in the FIB chamber;
transferring the sample outside of the FIB chamber and inverting the sample;
loading the inverted sample back to the FIB chamber;
thinning the inverted sample in the FIB chamber to obtain the specimen-; and
unloading the specimen out of the FIB chamber.

2. The method of claim 1, wherein transferring the lamella outside of the FIB chamber to a grid comprises:
transferring the sample outside of the FIB chamber using a probe needle;
rotating the probe to overturn the sample and orientate the sample; and
placing the sample on the grid.

3. The method of claim 2, wherein the grid and the sample are laid flat in the FIB chamber in the step of loading the sample with the grid into the FIB chamber.

4. The method of claim 3, wherein the step of transferring the sample outside of the FIB chamber and inverting the sample comprises:
clamping the grid by using fixtures after transferring the sample outside of the FIB chamber and adjusting an orientation of the clamped grid so that the sample carried on the grid is inverted.

5. The method of claim 1, wherein thinning the inverted sample in the FIB chamber comprising unloading the inverted sample, orienting the inverted sample upside down and loading the inverted sample into the FIB chamber for thinning until a predetermined thickness is achieved and the specimen is obtained.

6. The method of claim 5, wherein the predetermined thickness of the specimens less than 100 nm.

7. The method of claim 1, wherein the grid is a copper grid having a silicon film thereon and the sample is placed on the silicon film.

8. The method of claim 1, further comprising plating a second metal strip on a surface of the bulk sample before cutting the lamella off the bulk sample by forming trenches through FIB milling.

9. The method of claim 1, wherein the first metal strip is a platinum strip.

10. The method of claim 8, wherein the second metal strip is a platinum strip.
